(19) United States
(12) Patent Application Publication
(10) Pub. No.: US 2023/0092244 A1
(43) Pub. Date: Mar. 23, 2023

(54) THREE-DIMENSIONAL TRANSISTOR WITH FIN-SHAPED GATE

(71) Applicant: Intel Corporation, Santa Clara, CA (US)

(72) Inventors: Noriyuki Sato, Hillsboro, OR (US); Hui Jae Yoo, Hillsboro, OR (US); Van H. Le, Beaverton, OR (US); Sarah Atanasov, Beaverton, OR (US); Abhishek A. Sharma, Hillsboro, OR (US)

(21) Appl. No.: 17/481,760

(22) Filed: Sep. 22, 2021

(51) Int. Cl. H01L 29/786; H01L 29/423; H01L 29/66

(52) U.S. Cl. CPC H01L 29/7869; H01L 29/78696; H01L 29/42376; H01L 29/66969

(57) ABSTRACT

Described herein are back-gated transistors with fin-shaped gates, and IC devices including such transistors. The transistor includes a gate electrode formed over a support structure, where the gate electrode includes a metal fin that extends perpendicular to the support structure. A gate dielectric formed of a metal oxide film is deposited over the gate electrode and conforming to the fin shape, and a channel material formed of a high mobility oxide semiconductor film is deposited over the gate dielectric, the channel material also conforming to the fin shape. Source and drain contacts may be arranged so that the fin creates a channel with a larger channel width or a longer channel length.

### TECHNICAL FIELD

This disclosure relates generally to the field of integrated circuit (IC) structures and devices, and more specifically, to back-gated transistors incorporated in such IC structures and devices.

### BACKGROUND

Conventional transistors have a channel extending between a source region and a drain region, and a gate coupled to the channel to turn the transistor on or off. The source region and drain region are each coupled to a respective contact that applies a voltage to the region. Similarly, the gate is connected to a contact to apply a current to the gate. In back-gated transistors, the gate and the gate contact are on a back-side of the device, and source and drain contacts are on a front-side of the device.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a perspective view of a prior-art back-gated transistor.

FIG. 2 is a perspective view of a transistor with a fin-shaped gate, according to some embodiments of the present disclosure.

FIG. 3 is a perspective view of a fin-shaped gate for use in a transistor, according to some embodiments of the present disclosure.

FIG. 4 is a cross-section AA′ of the transistor with a fin-shaped gate shown in FIG. 2, according to some embodiments of the present disclosure.

FIG. 5 is a perspective view of a first contact arrangement for a transistor with a fin-shaped gate, according to some embodiments of the present disclosure.

FIG. 6 is a perspective view of a second contact arrangement for a transistor with a fin-shaped gate, according to some embodiments of the present disclosure.

FIG. 7 is a flow diagram of an example method for fabricating a transistor with a fin-shaped gate, according to some embodiments of the present disclosure.

FIGS. 8A and 8B are top views of a wafer and dies that include one or more transistors with fin-shaped gates in accordance with any of the embodiments disclosed herein.

FIG. 9 is a cross-sectional side view of an IC device that may include one or more transistors with fin-shaped gates in accordance with any of the embodiments disclosed herein.

FIG. 10 is a cross-sectional side view of an IC device assembly that may include one or more transistors with fin-shaped gates in accordance with any of the embodiments disclosed herein.

FIG. 11 is a block diagram of an example computing device that may include one or more transistors with fin-shaped gates in accordance with any of the embodiments disclosed herein.

### DETAILED DESCRIPTION

Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

In general, a field-effect transistor (FET), e.g., a metal-oxide-semiconductor (MOS) FET (MOSFET), is a three-terminal device that includes source, drain, and gate terminals and uses electric field to control current flowing through the device. A FET typically includes a channel material, a source region and a drain region provided in the channel material, and a gate stack that includes a gate electrode material, alternatively referred to as a “work function” material, provided over a portion of the channel material between the source and the drain regions, and, optionally, also includes a gate dielectric material between the gate electrode material and the channel material.

Conventional FETs are controlled using a source contact that is coupled to the source region, a gate contact that is coupled to the gate stack, and a drain contact that is coupled to the drain region. Each contact can apply a voltage to the respective region, e.g., the source contact applies a voltage to the source region, and the gate contact applies a voltage to the gate stack. Various arrangements for the source, gate, drain, and contacts have been realized. For example, in some prior transistors, the source and drain regions, and the source and drain contacts, are on the front-side of the device; the gate may be on either the front-side or the back-side. In other arrangements, the source and drain regions and contacts are on the back-side of the device. In still other arrangements, the source region and source contact are on the front-side of the device, while the drain region and drain contact are on the back-side of the device, or vice versa; as is commonly known, source and drain terminals are interchangeable in transistors.

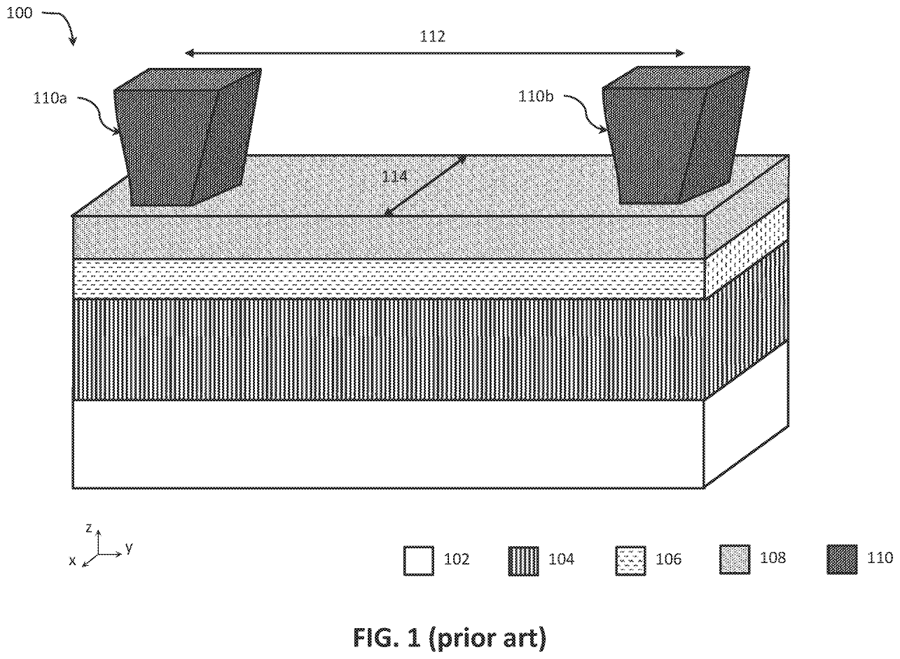

FIG. 1 shows a typical arrangement for a back-gated transistor. The transistor 100 includes a support structure 102, a gate electrode 104 formed over the support structure 102, a gate dielectric 106 formed over the gate electrode 104, and a channel 108 formed over the gate dielectric 106. Two contacts 110a and 110b are formed on opposite sides of the channel 108. The channel 108 may have source and drain regions (S/D regions) formed therein, with one S/D region under each of the contacts 110a and 110b.

The transistor 100 has a channel length 112, which corresponds to the length of the channel 108 between the first contact 110a and the second contact 110b. Because the channel 108 is planar, the channel length 112 is a straight-line distance between the two contacts 110a and 110b. The transistor 100 also has a channel width 114, which is the width of the channel 108. The channel width 114 is the width of the channel 108 in the x-direction in the coordinate system shown in FIG. 1, i.e., the distance across the channel 108 in a direction perpendicular to the channel length 112.

In general, it is desirable to decrease the size of the transistor 100, so that IC designers can fit more transistors within a given circuit area. However, decreasing the size of the transistor 100 decreases the channel length 112 and/or the channel length 114. When the transistor 100 is turned on, current flows between the first contact 110a and the second contact 110b through the channel 108. The amount of current that can flow through the channel 108 is dependent on the width of the channel; as the channel width 114 decreases, less current can flow through the channel 108. If the channel width becomes too small, the transistor 100 may not reliably turn on.

Furthermore, as the channel length 112 decreases, the transistor 100 is more likely to experience leakage current between the source and the drain in the off state. This leakage reduces device reliability and can have considerable negative effects on power consumption. Particularly in transistors with low threshold voltages to cause transistors to turn, subthreshold leakage can become a significant power drain on the device. Therefore, it is desirable to reduce leakage currents in transistors while maintaining a high transistor density across the device.

Described herein are transistors with fin-shaped gate electrodes and corresponding methods and devices. The transistor includes a gate electrode formed over a support structure, e.g., directly over the support structure, or with one or more layers (e.g., insulating layers, metal layers for routing signals, etc.) between the gate electrode and the support structure. A portion of the electrode extends in a direction perpendicular to the support structure, giving the electrode a fin shape. A gate dielectric, such as a gate oxide, may be formed over the fin-shaped gate electrode. A channel material is formed over the gate electrode, e.g., over the gate dielectric. The channel material conforms to the shape of the fin, with some of the channel material over a lower base portion of the electrode, some of the channel material over the higher fin portion of the electrode, and some of the channel material along the sides of the fin. The channel material may be deposited using a conformal deposition process so that both the top and sidewalls of the fin are covered by the channel material.

Two S/D contacts are formed over the channel material. In one embodiment, each of the respective S/D contacts wraps around a different portion of the fin. In this example, the channel width may be wider than the channel width 114 shown in FIG. 1, because the channel width goes up and over the fin and back down the other side of the fin. In another embodiment, each of the respective S/D contacts is formed over the base of the gate electrode, on either side of the fin. In this example, the channel length may be longer than the channel length 112 shown in FIG. 1, because the channel region goes up and over the fin and back down the other side of the fin.

The transistor with a fin-shaped gate described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well known features are omitted or simplified in order not to obscure the illustrative implementations.

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

The drawings are intended to show relative arrangements of the elements therein, and the device assemblies of these figures may include other elements that are not specifically illustrated (e.g., various interfacial layers). Similarly, although particular arrangements of materials are discussed with reference to the drawings, intermediate materials may be included in the devices and assemblies of these drawings. Still further, although some elements of the various device views are illustrated in the drawings as being planar rectangles or formed of rectangular solids and although some schematic illustrations of example structures are shown with precise right angles and straight lines, this is simply for ease of illustration, and embodiments of these assemblies may be curved, rounded, or otherwise irregularly shaped as dictated by, and sometimes inevitable due to, the manufacturing processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of one or more non-planar transistor arrangements with asymmetric gate enclosures as described herein.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. The meaning of “a,” “an,” and “the” include plural references. The meaning of “in” includes “in” and “on.”

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. The terms “substantially,” “close,” “approximately,” “near,” and “about,” generally refer to being within +/−20% of a target value. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, as used herein, a “logic state” of a ferroelectric memory cell refers to one of a finite number of states that the cell can have, e.g. logic states “1” and “0,” each state represented by a different polarization of the ferroelectric material of the cell. In another example, as used herein, a “READ” and “WRITE” memory access or operations refer to, respectively, determining/sensing a logic state of a memory cell and programming/setting a logic state of a memory cell. In other examples, the term “connected” means a direct electrical or magnetic connection between the things that are connected, without any intermediary devices, while the term “coupled” means either a direct electrical or magnetic connection between the things that are connected or an indirect connection through one or more passive or active intermediary devices. The term “circuit” means one or more passive and/or active components that are arranged to cooperate with one another to provide a desired function. In yet another example, a “high-k dielectric” refers to a material having a higher dielectric constant (k) than silicon oxide. The terms “oxide,” “carbide,” “nitride,” etc. refer to compounds containing, respectively, oxygen, carbon, nitrogen, etc.

Example Transistor with Fin-Shaped Electrode

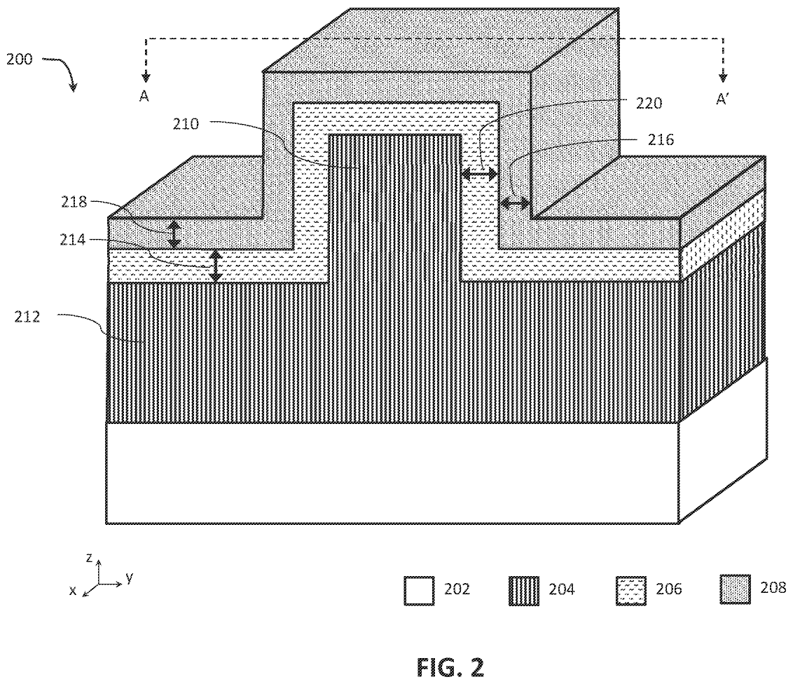

FIG. 2 is a perspective view of an example three-dimensional transistor 200 with a fin-shaped gate, according to some embodiments of the present disclosure. As shown, the transistor 200 is formed on a support structure 202, and the transistor 200 includes a gate stack comprising a gate electrode 204 and a gate dielectric 206. The gate electrode 204 has a base 212 and a fin 214, and the gate dielectric 206 is formed over and conforming to the shape of the gate electrode 204. A channel material 208 is over the gate dielectric 206 and also conforms to the shape of the gate electrode 204, and in particular, the shape of the gate stack that includes the fin-shaped gate electrode 204 and the gate dielectric 206.

A number of elements referred to in the description of FIGS. 2 and 4-7 with reference numerals are illustrated in these figures with different patterns, with a legend showing the correspondence between the reference numerals and patterns being provided at the bottom or side of each drawing page containing FIGS. 2 and 4-7. For example, the legend in FIG. 2 illustrates that FIG. 2 uses different patterns to show the support structure 202, the gate electrode 204, the gate dielectric 206, and the channel material 208.

In general, implementations of the present disclosure may be formed or carried out on a substrate, such as a semiconductor substrate composed of semiconductor material systems including, for example, N-type or P-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. Although a few examples of materials from which the substrate may be formed are described here, any material that may serve as a foundation upon which a semiconductor device may be built falls within the spirit and scope of the present disclosure. In various embodiments the support structure 202 may include any such substrate that provides a suitable surface for providing the transistor 200. In some embodiments, one or more additional layers not shown in FIG. 2 are situated between the support structure 202 and the channel material 304.

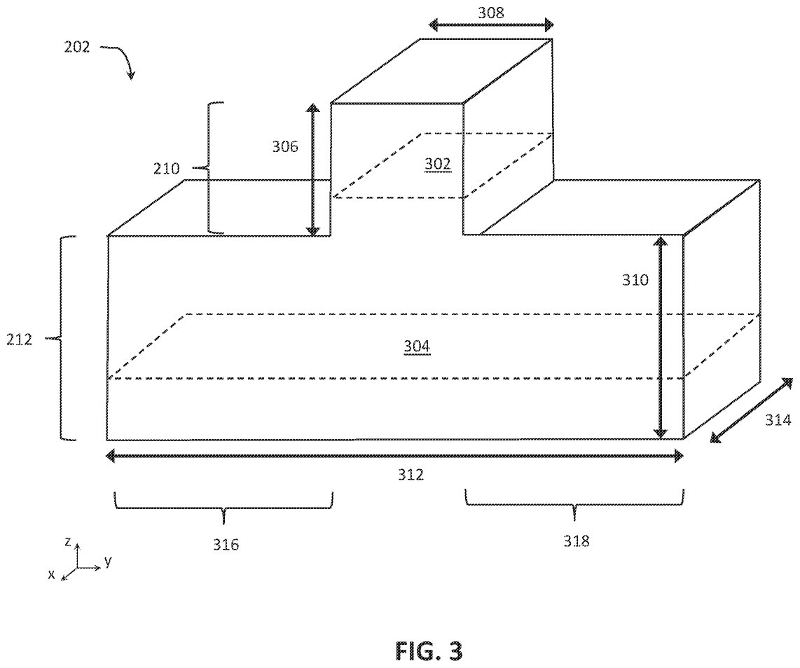

The gate electrode 204 is formed over the support structure 202. FIG. 3 is a perspective view of the fin-shaped gate 204. FIG. 3 illustrates various geometric features of the gate 204. The gate electrode 204 includes two portions: a fin 210 and a base 212. The fin 210 is formed over the base 212, and the fin 210 extends upwards from the base 212 in the z-direction in the coordinate system shown in FIGS. 2 and 3. The base 212 includes two portions 316 and 318 on either side of the fin 210, and a third portion located directly under the fin 210.

FIG. 3 illustrates a cross-section 304 through the fin 210 and a cross-section 306 through the base 212, where both cross-sections are parallel to the support structure 202 shown in FIG. 2, e.g., both cross-sections 304 and 306 are parallel to the x-y plane. The cross-section 304 of the fin 210 has a smaller area than the cross-section 306 of the base 212. While both cross-sections 304 and 306 have the same x-direction length 314, the fin 210 has a shorter y-direction length 308 than the y-direction length 312 of the base 212. In some examples, the x-direction length 314 of the gate electrode 204 is between, e.g., 5 nanometers and 1 micron. In some examples, the y-direction length 308 of the fin 210 is between, e.g., 5 nanometers and 1 micron. In some examples, the y-direction length 312 of the base 212 is between, e.g., 10 nanometers and 2 microns.

FIG. 3 also illustrates a height 306 of the fin 210 and a height 310 of the base 212. In some examples, the height 306 of the fin 210 is between, e.g., 5 nanometers and 500 nanometers. In some examples, the height 310 of the base 212 is between, e.g., 0.5 nanometers and 100 nanometers.

Although the fin 210 illustrated in FIGS. 2 and 3 is shown as having a rectangular cross-section in a y-z plane of the reference coordinate system shown, the fin 210 may instead have a cross-section that is rounded or sloped at the “top” of the fin 210. The gate dielectric 206 and channel material 208 formed over the fin 210 may conform to this rounded or sloped fin 210.

The gate electrode 204 may include at least one P-type work function material or N-type work function material, depending on whether the transistor 200 is a P-type metal-oxide-semiconductor (PMOS) transistor or an N-type metal-oxide-semiconductor (NMOS) transistor. P-type work function materials include, but are not limited to, ruthenium, palladium, platinum, cobalt, nickel, and conductive metal oxides (e.g., ruthenium oxide). N-type work function materials include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). For example, a P-type work function metal may be used as the gate electrode 204 when the transistor 200 is a PMOS transistor, and an N-type work function metal may be used as the gate electrode 204 when the transistor 200 is an NMOS transistor.

In some embodiments, the gate electrode 204 may consist of a stack of two or more electrode layers. In some embodiments, one or more electrode layers (e.g., one or more metal layers in the fin 210) are work function layers, and at least one electrode layer (e.g., one or more layers in the base 212) are fill layers. Further layers not illustrated in FIG. 2 may be included above or below the gate electrode 204 for other purposes, such as to act as a diffusion barrier layer or/and an adhesion layer.

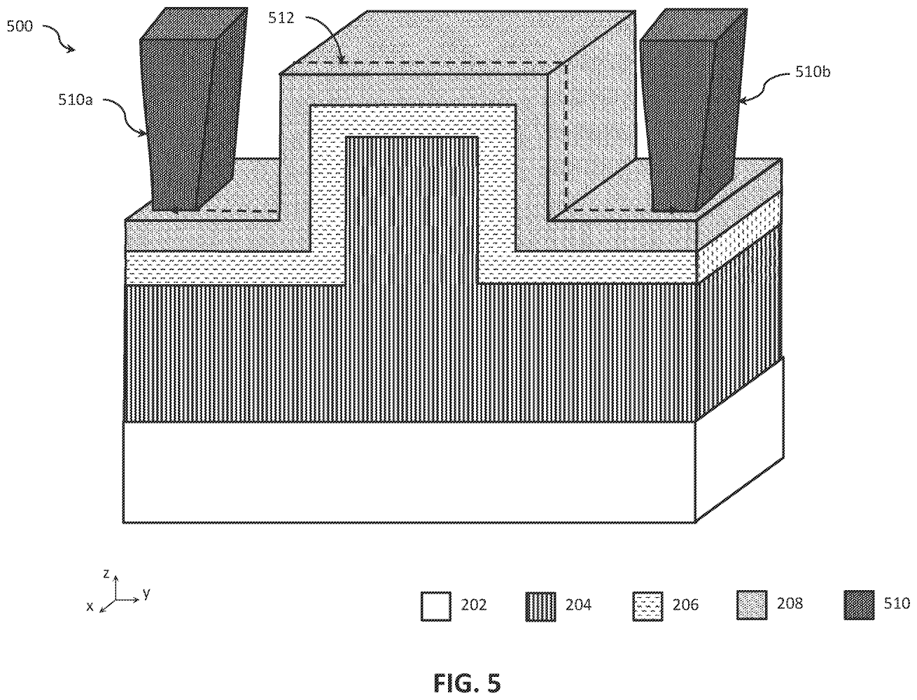

In some embodiments, different work function materials may be included in the gate electrode 204. In particular, if the transistor 200 is an NMOS transistor, the fin 210 may include an N-type work function material, while the base 212 includes a P-type work function material. Alternatively, if the transistor 200 is a PMOS transistor, the fin 210 may include a P-type work function material, while the base 212 includes an N-type work function material. For example, in the embodiment shown in FIG. 5, where the contacts are formed over the base 212, the material forming the fin 210 may be used to set the work function, while a different, non-work function material forms the base 212. This avoids unwanted interaction between the contacts and the base 212.

The gate electrode 204 may be formed by depositing one or more layers of electrode material over the support structure 202 and using an etching process to form the fin 210. For example, the gate electrode 204 may be patterned using any suitable patterning techniques, e.g., photolithographic or electron-beam patterning, possibly in combination with using a mask, e.g., a hardmask, and a suitable etching process is used to remove portions of the gate electrode 204, e.g., using dry etch, wet etch, reactive ion etch (RIE), ion milling, etc. In some embodiments, a mask layer is between the material forming the base 212 and the material forming the fin 210; in such embodiments, the fin 210 is etched, while the base 212 is left intact.

Alternatively, the base 212 and the fin 210 may be formed sequentially, e.g., by first depositing the base 212 in a first area (e.g., the area illustrated by the cross-section 306), and then depositing the fin 210 in a second, smaller area (e.g., the area illustrated by the cross-section 304).

In some embodiments, the transistor 200 may be a thin film transistor (TFT). A TFT is a field-effect transistor made by depositing thin films of materials over a supporting layer (e.g., the support structure 202), where the supporting layer is typically non-conductive. This differs from traditional transistor processing, in which a semiconductor channel is formed in the support structure, e.g., in a silicon wafer, and the contacts and gate electrode are deposited over the channel. In TFT embodiments, the gate electrode 204 may be deposited as one or more layers of thin film. For example, one or more layers of metal are deposited as a thin film or thin films, and an upper portion is then etched to form the fin shape, as described above. As another example, one or more layers of metal are deposited as thin films to form the base 212, a mask is laid down over the base 212, and one or more additional layers of metal are deposited as thin films to form the fin 210.

Turning back to FIG. 2, the gate dielectric 206 is over the gate electrode 204. In some embodiments, the gate dielectric 206 may include one or more high-k dielectrics, such as high-k metal oxides. Examples of high-k materials that may be used in the gate dielectric 206 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

The gate dielectric 206 may be deposited using a conformal deposition process, such as atomic layer deposition (ALD) or chemical vapor deposition (CVD). Conformal deposition generally refers to deposition of a certain coating on any exposed surface of a given structure. A conformal coating may, therefore, be understood as a coating that is applied to exposed surfaces of a given structure, and not, for example, just to the horizontal surfaces. As illustrated in FIG. 2, the gate dielectric 206 coats the sides of the fin 210 as well as the top of the fin 210 and the exposed top of the base 212 (i.e., the tops of the portions 316 and 318 of the base 212), thus forming a continuous gate dielectric over the fin-shaped gate electrode 204. In some embodiments, an annealing process may be carried out on the gate dielectric 206 during manufacture of the transistor 200 to improve the quality of the gate dielectric 206.

The gate dielectric 206 may be deposited as a thin film. The gate dielectric 206 may have a thickness 214 measured in the direction of the z-axis of the reference coordinate system shown in FIG. 2, i.e., the thickness of the gate dielectric 206 over the portions 316 and 318 of the base 212 and the top of the fin 210. The gate dielectric 206 also has a thickness 216 measured in the direction of the y-axis of the reference coordinate system, i.e., the thickness 216 along the sides of the fin 210. The thicknesses 214 and 216 may be the same or may differ based on the deposition process, e.g., the thickness 214 may be slightly greater than the thickness 216. Either or both of the thicknesses 214 and 216 may be, in some embodiments, between 0.5 nanometers and 100 nanometers, including all values and ranges therein (e.g., between 2 and 6 nanometers).

The channel material 208 is over the gate dielectric 206. Like the gate dielectric 206, the channel material 208 may be deposited using a conformal deposition process, as described above. As illustrated in FIG. 2, the channel material 208 coats the sides of the fin 210 as well as the top of the fin 210 and the tops of the portions 316 and 318 the base 212 (with the gate dielectric 206 between the channel material 208 and the gate electrode 204). This forms a continuous channel over the fin-shaped gate stack.

In some embodiments, the channel material 208 may be composed of semiconductor material systems including, for example, N-type or P-type materials systems. In some embodiments, the channel material 208 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 208 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 200 is NMOS), the channel material 208 may advantageously include a III-V material having a high electron mobility, such as, but not limited to InGaAs, InP, InSb, and InAs. For some such embodiments, the channel material 208 may be a ternary III—V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel material 208 may be an intrinsic III-V material, i.e., a III-V semiconductor material not intentionally doped with any electrically active impurity. In alternate embodiments, a nominal impurity dopant level may be present within the channel material 208, for example to further fine-tune a threshold voltage Vt, or to provide HALO pocket implants, etc. Even for impurity-doped embodiments however, impurity dopant level within the channel material 304 may be relatively low, for example below 10¹⁵ dopant atoms per cubic centimeter (cm′), and advantageously below 10¹³ cm⁻³ . These materials may be amorphous or polycrystalline, e.g., having a crystal grain size between 0.5 nanometers and 100 nanometers.

For some example P-type transistor embodiments (i.e., for the embodiments where the transistor 200 is PMOS), the channel material 208 may advantageously be a group IV material having a high hole mobility, such as, but not limited to Ge or a Ge-rich SiGe alloy. For some example embodiments, the channel material 208 may have a Ge content between 0.6 and 0.9, and advantageously may be at least 0.7. In some embodiments with highest mobility, the channel material 208 may be intrinsic III-V (or IV for P-type devices) material and not intentionally doped with any electrically active impurity. In alternate embodiments, one or more a nominal impurity dopant level may be present within the channel material 208, for example to further set a threshold voltage (Vt), or to provide HALO pocket implants, etc. Even for impurity-doped embodiments however, impurity dopant level within the channel portion is relatively low, for example below 10¹⁵ cm′, and advantageously below 10¹³ cm⁻³ . These materials may be amorphous or polycrystalline, e.g., having a crystal grain size between 0.5 nanometers and 100 nanometers.

As noted above, in some embodiments, the transistor 200 is a TFT, and the channel material 208 is an active semiconductor material deposited as a thin film. At least a portion of the channel material 208 forms the channel of the TFT. If the transistor 200 is a TFT, the channel material 208 may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor 200 is a TFT, the channel material 208 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, a thin film channel material 208 may be deposited at relatively low temperatures, which allows depositing the channel material 208 within the thermal budgets imposed on back-end fabrication to avoid damaging other components, e.g., front end components such as logic devices.

As noted above, the channel material 208 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The channel material 208 may have a thickness 218 measured in the direction of the z-axis of the reference coordinate system shown in FIG. 2, i.e., the thickness of the channel material 208 the portions 316 and 318 of the base 212 and the top of the fin 210 (and over the gate dielectric 206). The channel material 208 also has a thickness 220 measured in the direction of the y-axis of the reference coordinate system, i.e., the thickness 220 along the sides of the fin 210. The thicknesses 218 and 220 may be the same or may differ based on the deposition process, e.g., the thickness 218 may be slightly greater than the thickness 220. Either or both of the thicknesses 218 and 220 may be, in some embodiments, between 0.5 nanometers and 100 nanometers, including all values and ranges therein.

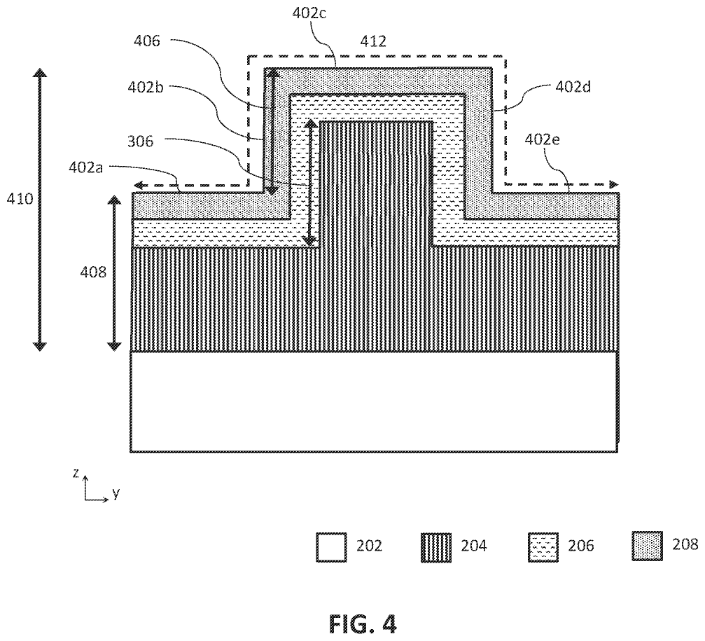

FIG. 4 is a cross-section AA′ of the transistor 200 shown in FIG. 2, according to some embodiments of the present disclosure. The channel material 208 has several surfaces 402 extending into the x-direction (into the page in FIG. 4): two horizontal surfaces 402a and 402e formed over the base portions 316 and 318 (shown in FIG. 3), respectively; a horizontal surface 402c formed over the fin 210; and two vertical surfaces 402b and 402d along the sides of the fin 210. The horizontal surfaces are parallel to the x-y plane, and the vertical surfaces are parallel to the x-z plane. The horizontal surfaces 402a and 402e formed over the base 212 are a first distance 408 from the support structure 202, and the horizontal surface 402c formed over the fin 210 is a second distance 410 from the support structure 202, where the second distance 410 is greater than the first distance 408.

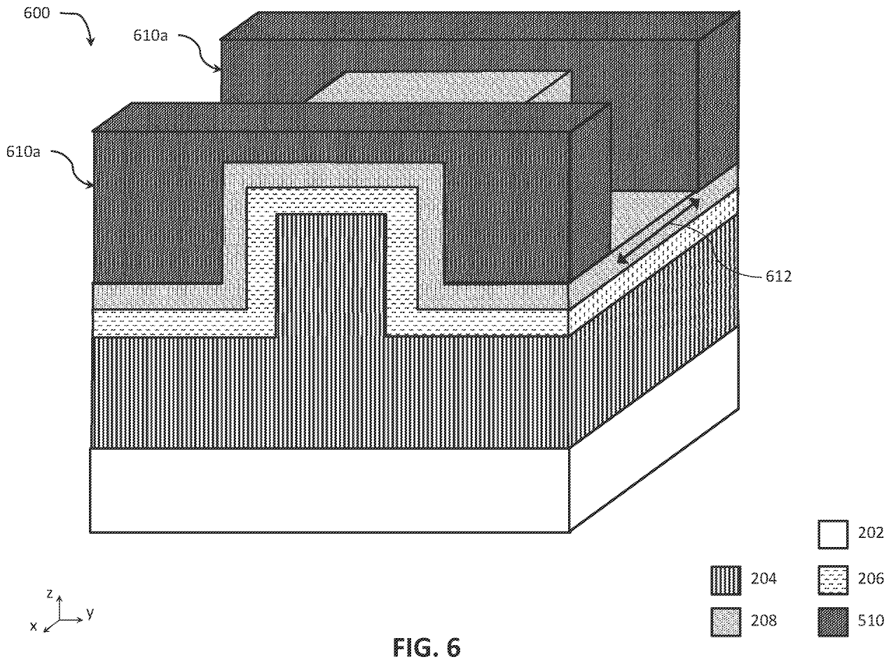

FIG. 4 illustrates a length 412 of the channel in a direction extending over the fin 210. The channel length 412 extends across each of the surfaces 402a-402e. Unlike the channel length 112 shown in FIG. 1, the length 412 is not a straight line, and extends over the top of the fin 202. This increases the size of the channel of the transistor without increasing the surface area in the x-y plane consumed by the transistor. Depending on the positioning of the S/D contacts, the channel arrangement can either increase the channel length (i.e., the distance between the S/D contacts) or the channel width (e.g., the width of the channel in the area between the S/D contacts). Two example S/D contact arrangements are illustrated in FIGS. 5 and 6.

The length 412 of the channel as it extends over the fin 210 is related to the size of the fin 210. As the gate dielectric 206 and channel material 208 both have thicknesses described with respect to FIG. 2, the length of the channel material over the top of the fin is larger than the y-direction length 308 of the fin 210. The height 406 of the channel material between the portion of the channel material 208 extending over the base 212 and the portion of the channel material 208 over the fin 210 may, in some cases, be the same as the height 306 of the fin. In some cases, due to variations in thicknesses across the deposited gate dielectric 206 and channel material 308, the heights 306 and 406 may differ slightly.

Example Contact Arrangements for Transistors with Fin-Shaped Electrodes

FIG. 5 is a perspective view of a first contact arrangement for a device 500 with a fin-shaped gate, according to some embodiments of the present disclosure. The device 500 includes the transistor 200 as described with respect to FIGS. 2-4. In this example, two contacts 510a and 510b are formed on either side of the fin 210, with the fin 210 positioned between the contacts 510a and 510b. The contacts 510 are formed over the base 212, and in particular, over two different portions of the base 212, where one portion is over one side of the fin 210 (e.g., the portion 316 shown in FIG. 3), and the other portion is over the other side of the fin 210 (e.g., the portion 318 shown in FIG. 3). Said another way, the contact 510a is formed over the channel surface 402a shown in FIG. 4, and the contact 510b is formed over the channel surface 402e shown in FIG. 4.

A channel length 512, which is similar to the length 412 and extends between the two contacts 510a and 510b, is illustrated in FIG. 5. The channel length 512 represents a shortest path in the channel material 208 between the two contacts 510; unlike the example shown in FIG. 1, the channel length 512 is not a straight line, but instead extends up and over the fin 210. With the contacts 510 arranged on either side of the fin 210, the channel length 512 is longer than the channel length 112 described with respect to FIG. 1, assuming the same surface area for the transistor 200 and transistor 100. Alternatively, using the arrangement shown in FIG. 5, an IC designer may design transistors with a smaller y-dimension (e.g., a shorter y-dimension length 312 for the base of the transistor) than the y-dimension of the transistor 100, while maintaining an adequately long channel length. The channel length 512 can be further increased by increasing the height of the fin 210, which is related to the channel height, as shown in FIG. 4.

S/D regions, not specifically shown in FIG. 5, may be formed in the channel material 208 below the contacts 510. The S/D regions may generally be formed using either an implantation/diffusion process or an etching/deposition process. In the former process, dopants such as boron, aluminum, antimony, phosphorous, or arsenic may be ion-implanted into the channel material to form the source and drain regions. An annealing process that activates the dopants and causes them to diffuse further into the channel material 208 typically follows the ion implantation process. In the latter process, the channel material 208 may first be etched to form recesses at the locations of the source and drain regions. An epitaxial deposition process may then be carried out to fill the recesses with material that is used to fabricate the source and drain regions. In some implementations, the S/D regions may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions may be formed using one or more alternate semiconductor materials such as germanium or a group III-V material or alloy. And in further embodiments, one or more layers of metal and/or metal alloys may be used to form the S/D regions.

In various embodiments, one or more layers of metal and/or metal alloys may be used to form the contacts 510. For example, the electrically conductive materials of the S/D contact electrodes 510 may include one or more metals or metal alloys, with materials such as copper, ruthenium, palladium, platinum, cobalt, nickel, hafnium, zirconium, titanium, tantalum, and aluminum, tantalum nitride, tungsten, doped silicon, doped germanium, or alloys and mixtures of any of these. In some embodiments, the contacts 510 may include one or more electrically conductive alloys, oxides, or carbides of one or more metals. In some embodiments, the contacts 510 may include a doped semiconductor, such as silicon or another semiconductor doped with an N-type dopant or a P-type dopant. Metals may provide higher conductivity, while doped semiconductors may be easier to pattern during fabrication. In some embodiments, the contacts 510 may include both a semiconductor and a metal, e.g., an ALD-deposited doped oxide semiconductor followed by metal. Although FIG. 5 illustrates the first and second contacts 510 with a single pattern, suggesting that the material composition of the first and second contacts 510 is the same, this may not be the case in some other embodiments of the transistor 500. Thus, in some embodiments, the material composition of the contact 510a may be different from the material composition of the second contact 510b.

FIG. 6 is a perspective view of a second contact arrangement for a device 600 with a fin-shaped gate, according to some embodiments of the present disclosure. The device 600 includes the transistor 200 as described with respect to FIGS. 2-4. In this example, two contacts 610a and 610b wrap around different portions of the fin 210 and extend across respective portions of the base 212. Each contact 610 extends across the transistor 200 in the y-direction, e.g., each of the contacts 610 extends across all five channel surfaces 402a-402e shown in FIG. 4. In some embodiments, the contacts 610 may not extend fully to the outer edges of the lower horizontal surfaces 402a and 402e. A portion of the fin 210 and a portion of the base 212 are between the two contacts 610a and 610b, not covered by a contact. A channel length 612 extends between the two contacts 610a and 610b.

In this example, the channel width, corresponding to the length 412 shown in FIG. 4, may be greater than the channel width 114 described with respect to FIG. 1. Unlike the example shown in FIG. 1, the channel is not planar, but is folded over the gate electrode 206 (and in particular, over the fin 210), which increases the channel width compared to a planar transistor structure. Alternatively, using the arrangement shown in FIG. 6, an IC designer may design transistors with a smaller y-dimension (e.g., a shorter y-dimension length 312 for the base of the transistor) than the y-dimension of the transistor 100, while maintaining an adequately large channel width. The channel width can be further increased by increasing the height of the fin 210, which is related to the channel size, as shown in FIG. 4.

The contacts 610a and 610b may include any of the contact materials described with respect to FIG. 5 and indicated by the pattern 510. Furthermore, S/D regions, not specifically shown in FIG. 6, may be formed in the portions of the channel material 208 under the contacts 610a and 610b. The S/D regions may include similar materials described with respect to FIG. 5 and be formed in a similar manner as described with respect to FIG. 5.

The arrangements shown in FIGS. 2-6 (and other figures of the present disclosure) are intended to show relative arrangements of some of the components therein, and that the arrangement with the transistors or devices, or portions thereof, may include other components that are not illustrated. For example, although not specifically illustrated in FIG. 5 or 6, a dielectric spacer may be provided between the contacts 510a and 510b or the contacts 610a and 610b in order to provide additional electrical isolation between the source and drain electrodes. In another example, although not specifically illustrated in the figures, portions of the devices may be surrounded in an insulator material, such as any suitable ILD material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the devices may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

Example Method for Forming IC Device with Fin-Shaped Gate

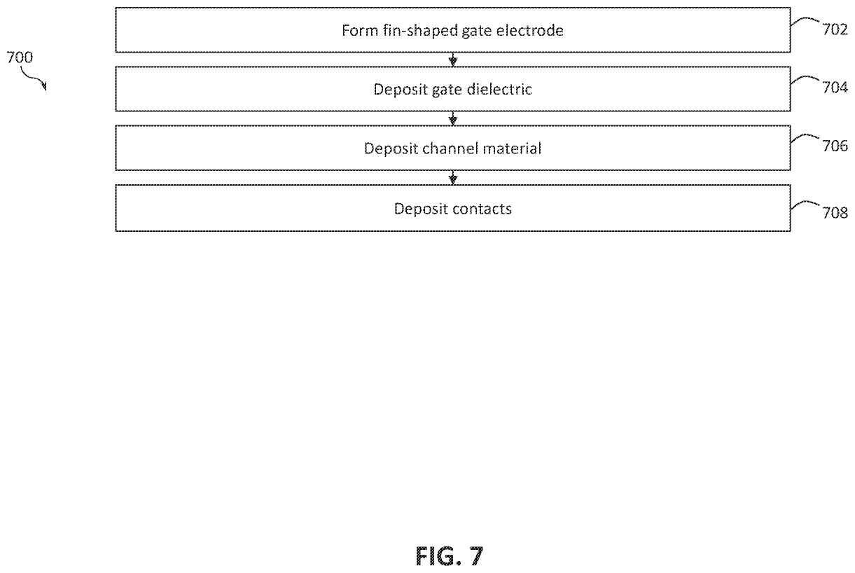

FIG. 7 is a flow diagram of an example method for fabricating a transistor with a fin-shaped gate, according to some embodiments of the present disclosure. The method begins with forming 702 a fin-shaped gate electrode, e.g., the gate electrode shown in FIG. 3 that has a fin 210 formed over a base 212. The gate electrode may be deposited over a support structure 102, e.g., over a support structure 102 with metal interconnects formed therein or thereon. The gate electrode 104 may be deposited so that it is coupled to an interconnect, e.g., a word line. The gate electrode 104 may be formed by additive processing (e.g., forming the base 212, and then forming the fin 210 over the base 212) or by subtractive processing (e.g., depositing a layer of metal, and then etching the fin 210).

The method proceeds with depositing 704 a gate dielectric over the fin-shaped gate electrode, e.g., the gate oxide 206 shown in FIG. 2. The gate dielectric conforms to the shape of the gate electrode, and the gate dielectric may be deposited using a conformal deposition process.

The method proceeds with depositing 706 a channel material, e.g., the channel material 208 shown in FIG. 2. The channel material conforms to the shape of the gate stack, and the channel material may be deposited using a conformal deposition process. Depositing 706 the channel material may include forming S/D regions in or over the channel material, as described with respect to FIGS. 5 and 6. The gate electrode, gate dielectric, and channel material form a transistor, e.g., the transistor 200.

The method proceeds with depositing 708 contacts for the source and drain over the transistor. Contacts 510a and 510b may deposited in the arrangement shown in FIG. 5, where the shape of the fin and the channel formed over the fin result in an increased channel length.

Alternatively, contacts 610a and 610b may be deposited the arrangement shown in FIG. 6, where the shape of the fin and the channel formed over the fin result in an increased channel width.

Example devices

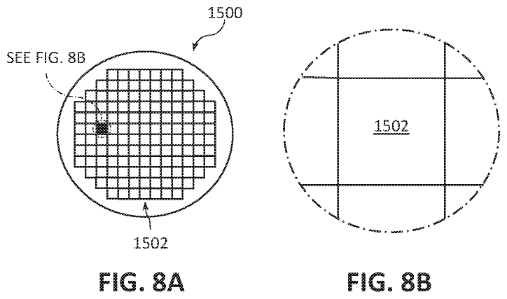

The transistors with fin-shaped gates disclosed herein may be included in any suitable electronic device. FIGS. 8-11 illustrate various examples of apparatuses that may include one or more of the transistors with fin-shaped gates disclosed herein.

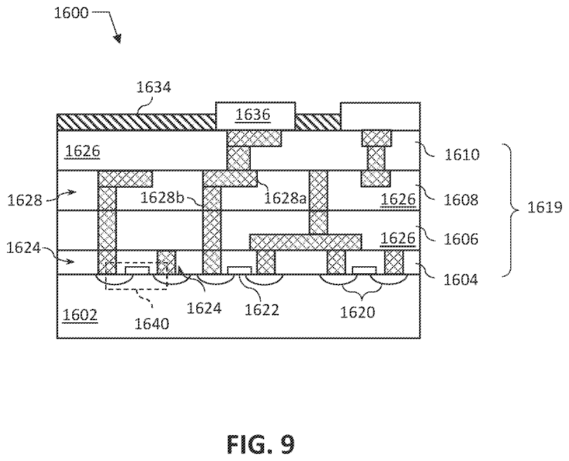

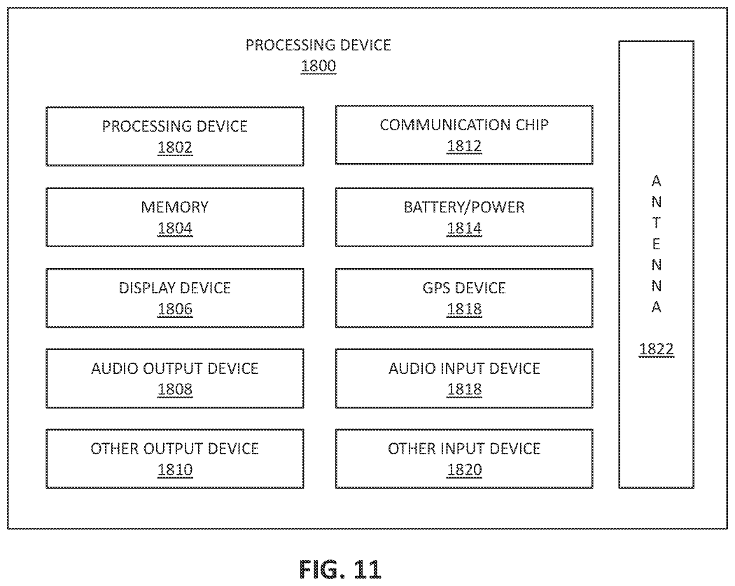

FIGS. 8A and 8B are top views of a wafer and dies that include one or more IC structures with one or more transistors with fin-shaped gates in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC structure (e.g., the IC structures as shown in any of FIGS. 2-6, or any further embodiments of the IC structures described herein). After the fabrication of the semiconductor product is complete (e.g., after manufacture of one or more IC structures with one or more transistors with fin-shaped gates as described herein, included in a particular electronic component, e.g., in a transistor or in a memory device), the wafer 1500 may undergo a singulation process in which each of the dies 1502 is separated from one another to provide discrete “chips” of the semiconductor product. In particular, devices that include one or more IC structures with one or more transistors with fin-shaped gates as disclosed herein may take the form of the wafer 1500 (e.g., not singulated) or the form of the die 1502 (e.g., singulated). The die 1502 may include one or more transistors (e.g., one or more of the transistors 1640 of FIG. 9, discussed below) and/or supporting circuitry to route electrical signals to the transistors, as well as any other IC components (e.g., one or more IC structures with one or more transistors with fin-shaped gates). In some embodiments, the wafer 1500 or the die 1502 may include a memory device (e.g., a static random-access-memory (SRAM) device), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 11) or other logic that is configured to store information in the memory devices or execute instructions stored in the memory array.

FIG. 9 is a cross-sectional side view of an IC device 1600 that may include one or more IC structures with one or more transistors with fin-shaped gates in accordance with any of the embodiments disclosed herein. The IC device 1600 may be formed on a substrate 1602 (e.g., the wafer 1500 of FIG. 8A) and may be included in a die (e.g., the die 1502 of FIG. 8B). The substrate 1602 may be any substrate as described herein. The substrate 1602 may be part of a singulated die (e.g., the dies 1502 of FIG. 8B) or a wafer (e.g., the wafer 1500 of FIG. 8A).

The IC device 1600 may include one or more device layers 1604 disposed on the substrate 1602. The device layer 1604 may include features of one or more transistors 1640 (e.g., metal-oxide-semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate electrode layer and a gate dielectric layer.

The gate electrode layer may be formed on the gate interconnect support layer and may consist of at least one P-type workfunction metal or N-type workfunction metal, depending on whether the transistor is to be a PMOS or an NMOS transistor, respectively. In some implementations, the gate electrode layer may consist of a stack of two or more metal layers, where one or more metal layers are workfunction metal layers and at least one metal layer is a fill metal layer. Further metal layers may be included for other purposes, such as a barrier layer or/and an adhesion layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 1640 along the source-channel-drain direction, the gate electrode may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may be implemented as a combination of U-shaped structures and planar, non-U-shaped structures. For example, the gate electrode may be implemented as one or more U-shaped metal layers formed atop one or more planar, non-U-shaped layers. In some embodiments, the gate electrode may consist of a V-shaped structure (e.g., when a fin of a FinFET transistor does not have a “flat” upper surface, but instead has a rounded peak).

Generally, the gate dielectric layer of a transistor 1640 may include one layer or a stack of layers, and the one or more layers may include silicon oxide, silicon dioxide, and/or a high-k dielectric material. The high-k dielectric material included in the gate dielectric layer of the transistor 1640 may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

Although not specifically shown in FIG. 9, the IC device 1600 may include one or more transistors with fin-shaped gates at any suitable location in the IC device 1600.

The S/D regions 1620 may be formed within the substrate 1602 adjacent to the gate 1622 of each transistor 1640, using any suitable processes known in the art. For example, the S/D regions 1620 may be formed using either an implantation/diffusion process or a deposition process. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion implantation process. In the latter process, an epitaxial deposition process may provide material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620. In some embodiments, an etch process may be performed before the epitaxial deposition to create recesses in the substrate 1602 in which the material for the S/D regions 1620 is deposited.

Electrical signals, such as power and/or input/output (I/O) signals, may be routed to and/or from the transistors 1640 of the device layer 1604 through one or more interconnect layers disposed on the device layer 1604 (illustrated in FIG. 9 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form an ILD stack 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC devices having more or fewer interconnect layers than depicted.

In some embodiments, the interconnect structures 1628 may include trench contact structures 1628a (sometimes referred to as “lines”) and/or via structures 1628b (sometimes referred to as “holes”) filled with an electrically conductive material such as a metal. The trench contact structures 1628a may be arranged to route electrical signals in a direction of a plane that is substantially parallel with a surface of the substrate 1602 upon which the device layer 1604 is formed. For example, the trench contact structures 1628a may route electrical signals in a direction in and out of the page from the perspective of FIG. 9. The via structures 1628b may be arranged to route electrical signals in a direction of a plane that is substantially perpendicular to the surface of the substrate 1602 upon which the device layer 1604 is formed. In some embodiments, the via structures 1628b may electrically couple trench contact structures 1628a of different interconnect layers 1606-1610 together.

The interconnect layers 1606-1610 may include a dielectric material 1626 disposed between the interconnect structures 1628, as shown in FIG. 9. The dielectric material 1626 may take the form of any of the embodiments of the dielectric material provided between the interconnects of the IC structures disclosed herein.

In some embodiments, the dielectric material 1626 disposed between the interconnect structures 1628 in different ones of the interconnect layers 1606-1610 may have different compositions. In other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include trench contact structures 1628a and/or via structures 1628b, as shown. The trench contact structures 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include via structures 1628b to couple the trench contact structures 1628a of the second interconnect layer 1608 with the trench contact structures 1628a of the first interconnect layer 1606. Although the trench contact structures 1628a and the via structures 1628b are structurally delineated with a line within each interconnect layer (e.g., within the second interconnect layer 1608) for the sake of clarity, the trench contact structures 1628a and the via structures 1628b may be structurally and/or materially contiguous (e.g., simultaneously filled during a dual-damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606.

The IC device 1600 may include a solder resist material 1634 (e.g., polyimide or similar material) and one or more bond pads 1636 formed on the interconnect layers 1606-1610. The bond pads 1636 may be electrically coupled with the interconnect structures 1628 and configured to route the electrical signals of the transistor(s) 1640 to other external devices. For example, solder bonds may be formed on the one or more bond pads 1636 to mechanically and/or electrically couple a chip including the IC device 1600 with another component (e.g., a circuit board). The IC device 1600 may have other alternative configurations to route the electrical signals from the interconnect layers 1606-1610 than depicted in other embodiments. For example, the bond pads 1636 may be replaced by or may further include other analogous features (e.g., posts) that route the electrical signals to external components.

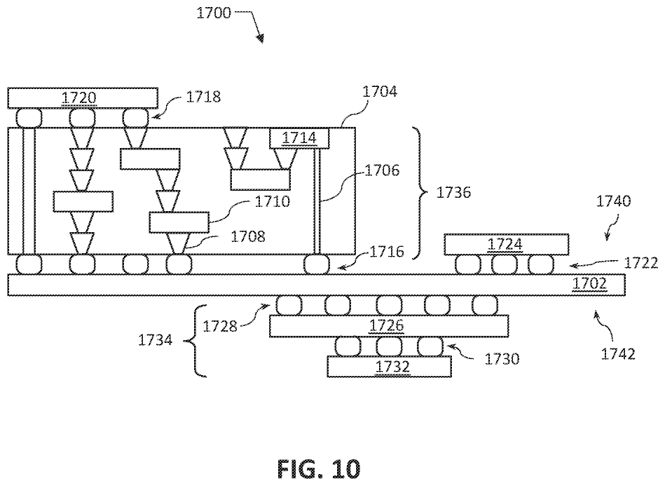

FIG. 10 is a cross-sectional side view of an IC device assembly 1700 that may include components having or being associated with (e.g., being electrically connected by means of) one or more IC structures with transistors with fin-shaped gates in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. In particular, any suitable ones of the components of the IC device assembly 1700 may include any of the transistors with fin-shaped gates, disclosed herein.

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 10 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702 and may include solder balls (as shown in FIG. 10), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 10, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 8B), an IC device (e.g., the IC device 1600 of FIG. 9), or any other suitable component. In some embodiments, the IC package 1720 may include one or more transistors with fin-shaped gates, as described herein. Generally, the interposer 1704 may spread a connection to a wider pitch or reroute a connection to a different connection. For example, the interposer 1704 may couple the IC package 1720 (e.g., a die) to a ball grid array (BGA) of the coupling components 1716 for coupling to the circuit board 1702. In the embodiment illustrated in FIG. 10, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer

The interposer 1704 may be formed of an epoxy resin, a fiberglass-reinforced epoxy resin, a ceramic material, or a polymer material such as polyimide. In some implementations, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to TSVs 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 1704. The interposer 1704 may further include one or more transistors with fin-shaped gates, as described herein. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 10 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 11 is a block diagram of an example computing device 1800 that may include one or more components including one or more IC structures with one or more transistors with fin-shaped gates in accordance with any of the embodiments disclosed herein. For example, any suitable ones of the components of the computing device 1800 may include a die (e.g., the die 1502 of FIG. 8B) having one or more transistors with fin-shaped gates as described herein. Any one or more of the components of the computing device 1800 may include, or be included in, an IC device 1600 (FIG. 9).

Any one or more of the components of the computing device 1800 may include, or be included in, an IC device assembly 1700 (FIG. 10).

A number of components are illustrated in FIG. 11 as included in the computing device 1800, but any one or more of these components may be omitted or duplicated, as suitable for the application. In some embodiments, some or all of the components included in the computing device 1800 may be attached to one or more motherboards. In some embodiments, some or all of these components are fabricated onto a single system-on-a-chip (SoC) die.

Additionally, in various embodiments, the computing device 1800 may not include one or more of the components illustrated in FIG. 11, but the computing device 1800 may include interface circuitry for coupling to the one or more components. For example, the computing device 1800 may not include a display device 1806, but may include display device interface circuitry (e.g., a connector and driver circuitry) to which a display device 1806 may be coupled. In another set of examples, the computing device 1800 may not include an audio input device 1824 or an audio output device 1808 but may include audio input or output device interface circuitry (e.g., connectors and supporting circuitry) to which an audio input device 1824 or audio output device 1808 may be coupled.

The computing device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-M RAM).

In some embodiments, the computing device 1800 may include a communication chip 1812 (e.g., one or more communication chips). For example, the communication chip 1812 may be configured for managing wireless communications for the transfer of data to and from the computing device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The computing device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The computing device 1800 may include battery/power circuitry 1814. The battery/power circuitry 1814 may include one or more energy storage devices (e.g., batteries or capacitors) and/or circuitry for coupling components of the computing device 1800 to an energy source separate from the computing device 1800 (e.g., AC line power).

The computing device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display, for example.

The computing device 1800 may include an audio output device 1808 (or corresponding interface circuitry, as discussed above). The audio output device 1808 may include any device that generates an audible indicator, such as speakers, headsets, or earbuds, for example.

The computing device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The computing device 1800 may include a GPS device 1818 (or corresponding interface circuitry, as discussed above). The GPS device 1818 may be in communication with a satellite-based system and may receive a location of the computing device 1800, as known in the art.

The computing device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The computing device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 1800 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 1800 may be any other electronic device that processes data.

### Select Examples

The following paragraphs provide various examples of the embodiments disclosed herein.

Example 1 provides an IC device including a support structure; a gate electrode over the support structure, the gate electrode including a fin extending in a direction perpendicular to the support structure, and the gate electrode including a metal; a gate dielectric comprising a metal oxide film, the gate dielectric over the gate electrode; and a channel material including a high mobility oxide semiconductor film, the channel material over the gate dielectric.

Example 2 provides the IC device of example 1, where the gate electrode further includes a base, and the fin is over the base of the gate electrode, extending upward from the base.

Example 3 provides the IC device of example 2, where a cross-section of the fin in a first plane parallel to the support structure has a smaller area than a cross-section of the base in a second plane parallel to the support structure.

Example 4 provides the IC device of example 2 or 3, where the base includes a first metal, and the fin includes a second metal different from the first metal.

Example 5 provides the IC device of any of examples 2-4, where the base includes a material having a p-type work function, and the fin includes a material having an n-type work function.

Example 6 provides the IC device of any of examples 2-4, where the base includes a material having an n-type work function, and the fin includes a material having a p-type work function.

Example 7 provides the IC device of any of the preceding examples, where the channel material includes at least one of indium oxide, gallium oxide, and zinc oxide, e.g., the channel material includes IGZO.

Example 8 provides the IC device of any of the preceding examples, where the channel material is a film having a thickness of less than 100 nanometers, e.g., less than 50 nanometers or less than 10 nanometers.

Example 9 provides the IC device of any of the preceding examples, further including a first contact coupled to the channel material and a second contact coupled to the channel material.

Example 10 provides the IC device of example 9, where the fin is between the first contact and the second contact.

Example 11 provides the IC device of example 10, where the gate electrode further includes a base, and the first contact and the second contact are each over a respective portion of the base.

Example 12 provides the IC device of example 9, where the first contact is over a first portion of the fin, and the second contact is over a second portion of the fin separated from the first portion.

Example 13 provides the IC device of example 12, where the first contact and the second contact each wrap around the fin.

Example 14 provides the IC device of example 10, where a shortest path through the channel material from the first contact to the second contact extends over the fin.

Example 15 provides an IC device including a support structure; a fin-shaped gate stack over the support structure, the gate stack including a metal fin and a gate oxide over the metal fin, where the gate oxide conforms to the metal fin; and a channel material extending over the gate stack, where the channel material conforms to the fin-shaped gate stack, the channel material having a first surface a first distance from the support structure and a second surface a second distance from the support structure, the second distance greater than the first distance.

Example 16 provides the IC device of example 15, where the gate stack further includes a metal base between the support structure and the metal fin.

Example 17 provides the IC device of example 15 or 16, where the channel material comprises at least one of indium oxide, gallium oxide, and zinc oxide, e.g., the channel material includes IGZO.

Example 18 provides the IC device of any of examples 15-17, where the channel material is a film having a thickness of less than 100 nanometers, e.g., less than 50 nanometers or less than 10 nanometers.

Example 19 provides the IC device of any of examples 15-18, further including a first contact coupled to the channel material and a second contact coupled to the channel material.

Example 20 provides the IC device of example 19, where the first contact has a first portion over the first surface of the channel material and a second portion over the second surface of the channel material.

Example 21 provides the IC device of example 19, where the first contact is over the first surface of the channel material, and is not over the second surface of the channel material.

Example 22 provides the IC device of example 15, where the channel material further has a third surface, the third surface is the first distance from the support structure, and the second surface is between the first surface and the third surface.

Example 23 provides the IC device of example 22, where a first contact is over the first surface, and a second contact is over the third surface.

Example 24 provides the IC device of example 22, where the channel material further has a first side surface extending between the first surface and the second surface, and a second side surface extending between the second surface and the third surface.

Example 25 provides method of fabricating an IC device, the method including forming a gate electrode over a support structure, the gate electrode having a fin extending in a direction perpendicular to the support structure, and the gate electrode including a metal; forming a gate oxide film over the gate electrode; forming a channel region over the gate oxide film, the channel region comprising a thin film of a channel material, the channel material comprising at least one of indium oxide, gallium oxide, and zinc oxide; and forming a pair of contacts over the channel region.

Example 26 provides the method of example 25, where forming the gate electrode includes forming a base portion of the gate electrode; and forming the fin of the gate electrode over the base portion.

Example 27 provides the method of example 26, where the base portion includes a first metal, and the fin includes a second metal different from the first metal.

Example 28 provides the method of example 25, where forming the gate electrode includes depositing an electrode material; and etching a portion of the electrode material to form the fin.

Example 29 provides the method of any of examples 25 to 28, where forming the gate oxide film includes conformally depositing a layer of gate oxide film over the gate electrode.

Example 30 provides the method of example 29, where forming the channel region includes conformally depositing the thin film of channel material over the gate dielectric, the thin film of channel material having a thickness of less than 100 nanometers.

Example 31 provides an IC device including a support structure; a fin-shaped gate stack over the support structure, the fin-shaped gate stack including a metal fin; a channel material extending over the fin-shaped gate stack, the channel material conforming to the fin-shaped gate stack; a first S/D contact coupled to a first portion of the channel material; and a second S/D contact coupled to a second portion of the channel material, where a shortest path through the channel material from the first S/D contact to the second S/D contact extends over the fin-shaped gate stack.

Example 32 provides the IC device of example 31, where the gate stack includes a gate electrode, the gate electrode including a metal base and the metal fin.

Example 33 provides the IC device of example 32, where the gate stack further includes a gate oxide film over the gate electrode, where the gate oxide film conforms to the metal fin.

Example 34 provides the IC device of example 32, where the base includes a first metal, and the metal fin includes a second metal different from the first metal.

Example 35 provides the IC device of example 34, where first metal has a p-type work function, and the second metal has an n-type work function.

Example 36 provides the IC device of example 34, where the first metal has an n-type work function, and the second metal has a p-type work function.

Example 37 provides the IC device of any of examples 31-36, where the metal fin is between the first S/D contact and the second S/D contact.

Example 38 provides an IC package that includes an IC die, including one or more of the memory/IC devices according to any one of the preceding examples. The IC package may also include a further component, coupled to the IC die.

Example 39 provides the IC package according to example 38, where the further component is one of a package substrate, a flexible substrate, or an interposer.

Example 40 provides the IC package according to examples 38 or 39, where the further component is coupled to the IC die via one or more first level interconnects.

Example 41 provides the IC package according to example 40, where the one or more first level interconnects include one or more solder bumps, solder posts, or bond wires.

Example 42 provides a computing device that includes a circuit board; and an IC die coupled to the circuit board, where the IC die includes one or more of the IC devices according to any one of the preceding examples (e.g., IC devices according to any one of examples 1-37), and/or the IC die is included in the IC package according to any one of the preceding examples (e.g., the IC package according to any one of examples 38-41).

Example 43 provides the computing device according to example 42, where the computing device is a wearable computing device (e.g., a smart watch) or hand-held computing device (e.g., a mobile phone).

Example 44 provides the computing device according to examples 42 or 43, where the computing device is a server processor.

Example 45 provides the computing device according to examples 42 or 43, where the computing device is a motherboard.

Example 46 provides the computing device according to any one of examples 42-45, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device comprising:
a support structure;
a gate electrode over the support structure, the gate electrode comprising a fin extending in a direction perpendicular to the support structure, the gate electrode comprising a metal;
a gate dielectric comprising a metal oxide film, the gate dielectric over the gate electrode; and
a channel material comprising a high mobility oxide semiconductor film, the channel material over the gate dielectric.

2. The IC device of claim 1, wherein the gate electrode further comprises a base, and the fin is over the base of the gate electrode, extending upward from the base.

3. The IC device of claim 2, wherein a cross-section of the fin in a first plane parallel to the support structure has a smaller area than a cross-section of the base in a second plane parallel to the support structure.

4. The IC device of claim 2, wherein the base comprises a first metal, and the fin comprises a second metal different from the first metal.

5. The IC device of claim 2, wherein the base comprises a material having a p-type work function, and the fin comprises a material having an n-type work function.

6. The IC device of claim 2, wherein the base comprises a material having an n-type work function, and the fin comprises a material having a p-type work function.

7. The IC device of claim 1, wherein the channel material comprises at least one of indium oxide, gallium oxide, and zinc oxide.

8. The IC device of claim 1, wherein the channel material comprises a film having a thickness of less than 100 nanometers.

9. The IC device of claim 1, further comprising a first contact coupled to the channel material and a second contact coupled to the channel material, wherein the fin is between the first contact and the second contact.

10. The IC device of claim 9, wherein the gate electrode further comprises a base, and the first contact and the second contact are each over a respective portion of the base.

11. The IC device of claim 1, further comprising a first contact coupled to the channel material and a second contact coupled to the channel material wherein the first contact is over a first portion of the fin, and the second contact is over a second portion of the fin separated from the first portion.

12. The IC device of claim 10, wherein the first contact and the second contact each wrap around the fin.

13. An integrated circuit (IC) device comprising:
a support structure;
a fin-shaped gate stack over the support structure, the gate stack comprising a metal fin and a gate oxide over the metal fin, wherein the gate oxide conforms to the metal fin; and
a channel material extending over the fin-shaped gate stack, wherein the channel material conforms to the fin-shaped gate stack, the channel material comprising:
a first surface a first distance from the support structure; and
a second surface a second distance from the support structure, the second distance greater than the first distance.

14. The IC device of claim 13, wherein the gate stack further comprises a metal base between the support structure and the metal fin.

15. The IC device of claim 13, wherein the channel material comprises at least one of indium oxide, gallium oxide, and zinc oxide.

16. The IC device of claim 13, wherein the channel material comprises a film having a thickness of less than 100 nanometers.

17. The IC device of claim 16, further comprising a first contact coupled to the channel material and a second contact coupled to the channel material, wherein the first contact has a first portion over the first surface of the channel material and a second portion over the second surface of the channel material.

18. The IC device of claim 16, further comprising a first contact coupled to the channel material and a second contact coupled to the channel material, wherein the first contact is over the first surface of the channel material, and is not over the second surface of the channel material.

19. A method of fabricating an integrated circuit (IC) device, the method comprising:
forming a gate electrode over a support structure, the gate electrode having a fin extending in a direction perpendicular to the support structure, the gate electrode comprising a metal;
forming a gate oxide film over the gate electrode;
forming a channel region over the gate oxide film, the channel region comprising a thin film of a channel material, the channel material comprising at least one of indium oxide, gallium oxide, and zinc oxide; and
forming a pair of contacts over the channel region.

20. The method of claim 19, wherein forming the gate electrode comprises:
forming a base portion of the gate electrode; and
forming the fin of the gate electrode over the base portion, wherein the base portion comprises a first metal, and the fin comprises a second metal different from the first metal.
